(19) United States
(12) Patent Application Publication
(10) Pub. No.: US 2021/0335639 A1
(43) Pub. Date: Oct. 28, 2021

(54) SCHEDULING METHOD AND DEVICE FOR BATCH PROCESSING MACHINE

(71) Applicant: Shanghai Huali Integrated Circuit Corporation, Shanghai (CN)

(72) Inventors: Chunxia Qian, Shanghai (CN); Jing Zhou, Shanghai (CN); Xiaolin Cui, Shanghai (CN); Qiuchen Xu, Shanghai (CN)

(21) Appl. No.: 17/185,447

(22) Filed: Feb. 25, 2021

(30) Foreign Application Priority Data
Apr. 27, 2020 (CN) 202010345145.0

(51) Int. Cl. H01L 21/67; G06N 3/12; G06Q 10/06

(52) U.S. Cl. CPC H01L 21/67276; G06N 3/126; G06Q 50/04; G06Q 10/06313; G06Q 10/06312

(57) ABSTRACT

The invention provides a scheduling method for batch processing machines, which is suitable for scheduling of workpieces on multiple batch processing machines in a manufacturing factory. The scheduling method for batch processing machines includes: establishing a scheduling model based on multiple scheduling objectives of the multiple batch processing machines and the workpieces, and the multiple scheduling objectives include meeting the delivery date of the workpieces, improving the capacity utilization rate and batch size of the batch processing machine, reducing the final production cycle time of the workpieces, and using Genetic Algorithm to determine the optimal scheduling scheme of the scheduling model.

### CROSS-REFERENCES TO RELATED APPLICATIONS

This application claims priority to Chinese patent application No. CN202010345145.0, filed on Apr. 27, 2020 at CNIPA, and entitled “A SCHEDULING METHOD AND DEVICE FOR BATCH PROCESSING MACHINE”, the disclosure of which is incorporated herein by reference in entirety.

### TECHNICAL FIELD

The present invention relates to semiconductor manufacturing, and particularly to a scheduling method and device for a batch processing machine.

### BACKGROUND

In a semiconductor production line, usually one machine can produce one or a few workpieces at one time. The other workpieces which are waiting for operation are sorted according to dispatch rules and will be assigned to the machine in order for operation. Most times, a type of batch processing machine is used wherein multiple workpieces with the same process conditions are combined into a batch and processed at the same time, in this type of batch processing machines. At the same time, production lines usually group together the process machines of the same or similar functions for completing these process steps more efficiently. These process machines are often arranged into parallel batch processing in production lines.

The batch processing machines can process many workpieces at the same time unlike the single-wafer processing machines; meanwhile, the operation time for each batch on these batch processing machines is generally longer. The various combinations of batches and the orders of operations can have a great impact on the delivery time and the next processing step. Optimizing the batch operation is often a difficult aspect in automatic scheduling. To optimize a batch processing involves two aspects. First, the sequencing theory is applied to group batches in order to obtain local optimal solutions, and second, the scheduling theory is applied to perform scheduling.

At present, the heuristic scheduling rules and the intelligent algorithm scheduling rules are the two main scheduling methods.

Among them, the heuristic scheduling rules generally determine multiple known and clear rules first, and then design the calculation process based on these rules. Through multiple steps of calculation and decisions, optimal solutions can be finally obtained. The heuristic rules are simple to implement, and involves minimal calculation, they show high operating efficiency in fast production cycles, therefore they are suitable for applications in large scale manufacturing. However, heuristic scheduling must be based on known rules, they require users to possess lots of experience based on experimentation, evaluation, or trial-and-error methods, so they are only suitable for short term and partial improvements of some specific problems. The type of heuristic scheduling rules is poor in adapting to changes of the manufacturing environment. Changes in work conditions will cause large deviations in scheduling results, which cannot effectively improve the overall performance of production lines.

Research based on intelligent algorithms is also suspended in the scheduling link, and the batching link is not taken into consideration, that is, the optimal batching results are obtained through the sequencing theory, and then intelligent algorithms such as genetic algorithms are used for scheduling. However, sorting and scheduling belong to fuzzy logic problems, where optimal results of sorting are used as inputs before scheduling, and the obtained scheduling results are not often necessarily optimal. Meanwhile, the intelligent algorithms are still in the research stage. The various assumptions of batch processing machines usually simplify conditions, which are acquired from limited practice in single machine or single process condition grouping batch, and the two links of grouping batch and scheduling are considered separately, so the intelligent algorithms fail to achieve the goal of overall realization and overall optimization.

In summary, the scheduling results of the existing scheduling methods are not stable and optimized, and human intervention is often needed. There is still a long way to go before reaching more than 95% fully automated scheduling goal.

In order to solve these problems, the present invention aims to propose a batch processing machine scheduling method, which is suitable for the scheduling problem of multiple batch processing machines. At the same time, the two links of batching and scheduling are considered as a whole, and the effect of overall optimization can be finally achieved.

### BRIEF SUMMARY OF THE DISCLOSURE

A brief overview of the disclosure is provided below.

According to some embodiments of the present disclosure, a batch processing machine scheduling method is provided, which is suitable for scheduling of workpieces on the multiple batch processing machines. The method for scheduling workpieces on multiple batch processing machines in a factory, comprising: establishing a scheduling model based on multiple scheduling objectives of the multiple batch processing machines and the workpieces, wherein the multiple scheduling objectives include meeting delivery dates of the workpieces, improving capacity utilization rate and batch sizes of the batch processing machines, and reducing production cycle time of the workpieces, and applying Genetic Algorithm to determine an optimal scheduling scheme of the scheduling model.

In some examples, applying the Genetic Algorithm to determine the optimal scheduling scheme of the scheduling model comprises: constructing an initial population based on process parameters of the workpieces and of the multiple batch processing machines, wherein the initial population includes several chromosomes, wherein each of the several chromosomes corresponds to a scheduling scheme that satisfies the scheduling model; iterating the Genetic Algorithm to among the initial population to determine an optimal chromosome; and decoding the optimal chromosome to obtain an optimal scheduling scheme corresponding to the optimal chromosome.

In some examples, constructing the initial population based on the process parameters of the workpieces and of the multiple batch processing machines comprises: setting a chromosome population size; and applying a double layer code design to generate the several chromosomes which satisfy the population size based on the process parameters of the workpieces and of the multiple batch processing machines to construct the initial population, wherein the double layer code design conforms to the scheduling model.

In some examples, the constructing the initial population based on the process parameters of the workpieces and of the multiple batch processing machines further comprises: reading data of calculation examples to obtain the process parameters of the workpieces; and setting the process parameters of the multiple batch processing machines.

In some examples, applying the double layer code design comprises: performing a first layer code based on a number and conditions of the workpieces, wherein the first layer code includes multiple sub-layers, wherein each of the multiple sub-layers corresponds to one condition; and applying a random function to initialize the multiple sub-layers and a second layer code under constraints of a number and conditions of the multiple batch processing machines.

In some examples, iterating the Genetic Algorithm among the initial population to determine the optimal chromosome comprises: setting a number of genetic iterations, parameters of genetic operation, and a fitness function, wherein the parameters of the genetic operation include mutation probability, crossover probability, and selection method; iterating the Genetic Algorithm on the initial population; in a response that the number of genetic iterations is reached, ending the iterating of the Genetic Algorithm; and defining the optimal chromosome as a chromosome with a largest fitness value after a last Genetic Algorithm iteration, wherein the fitness value is a value of the chromosome corresponding to the fitness function.

In some examples, each iteration of the Genetic Algorithm comprises: performing a mutation operation and a crossover operation on the chromosomes from a previous Genetic Algorithm iteration based on the mutation probability and the crossover probability to generate new chromosomes; calculating the fitness value of each of the new chromosomes based on the fitness function; and applying the selection method to the new chromosomes based on the fitness value of each of the new chromosomes, wherein only chromosomes meeting the population size are selected in a present iteration of the Genetic Algorithm.

In some examples, the setting fitness function comprises: setting the fitness function based on an objective function of the scheduling model; and calculating the fitness value of each new chromosome based on the fitness function, wherein the calculating comprises: decoding each new chromosome according to designing rules of the double layer code design to obtain the scheduling scheme corresponding to the new chromosome; determining an objective function value based on the scheduling scheme; and calculating the fitness value of each new chromosome based on the objective function value and the fitness function.

In some examples, the objective function is related to a completion time of the scheduling scheme, and wherein the decoding the chromosome to obtain the corresponding scheduling scheme comprises: splitting the double layer code design of the chromosomes to obtain a sub-layer workpiece sequence and a batch size corresponding to the chromosomes respectively; matching the sequence of the sub-layer workpieces to the batch size to form a batch result obtaining a start time and an operation time of each batch of workpieces according to the parameters of each batch of workpieces; and according to the sequence of the sub-layer workpieces, scheduling the batch results based on a scheduling principle to generate a scheduling scheme corresponding to the new chromosomes.

In some examples, the objective function is related to a completion time of the scheduling scheme, and the decoding the chromosome to obtain the corresponding scheduling scheme comprises: splitting the double layer code design of the chromosomes to obtain a sub-layer workpiece sequence and a batch size corresponding to the chromosomes respectively; matching the sequence of the sub-layer workpieces to the batch size to form a batch result; obtaining a start time and an operation time of each batch of workpieces according to the parameters of each batch of workpieces; and according to the sequence of the sub-layer workpieces, scheduling the batch results based on a scheduling principle to generate a scheduling scheme corresponding to the chromosomes.

In some examples, the method further comprises scheduling the workpieces to the multiple batch processing machines for processing based on the optimal scheduling scheme.

According to the present disclosure, a scheduling device is provided for scheduling workpieces on multiple batch processing machines, comprising: a memory unit; and a processor unit coupled to the memory unit, wherein the processor unit is configured to: establish a scheduling model based on multiple scheduling objectives of the multiple batch processing machines and the workpieces, wherein the multiple scheduling objectives include meeting delivery dates of the workpieces, improving capacity utilization rate and batch sizes of the batch processing machines, and reducing production cycle time of the workpieces; and apply Genetic Algorithm to determine an optimal scheduling scheme of the scheduling model.

In some examples, the processor unit is further configured to: construct an initial population based on process parameters of the workpieces and of the multiple batch processing machines, wherein the initial population includes a number of chromosomes, wherein each of the chromosome corresponds to a scheduling scheme that satisfies the scheduling model; iterating the Genetic Algorithm among the initial population to determine an optimal chromosome; and decode the optimal chromosome to obtain an optimal scheduling scheme corresponding to the optimal chromosome.

In some examples, the processor unit is further configured to: set a chromosome population size; and apply a double layer code design to generate chromosomes which satisfy the population size based on the process parameters of the workpieces and of the multiple batch processing machines to construct the initial population, wherein the double layer code design conforms to the scheduling model.

In some examples, the processor unit is further configured to: read data of calculation examples to obtain the process parameters of the workpieces; and set the process parameters of the batch processing machines.

In some examples, the processor unit is further configured to: perform a first layer code design based on a number and conditions of the workpieces, the first layer code design includes multiple sub-layers, and each sub-layer corresponds to one condition; and use a random function to initialize the multiple sub-layers and a second layer code under constraints of the number and conditions of the multiple batch processing machines.

In some examples, the processor unit is further configured to: set a number of genetic iterations, parameters of genetic operation, and a fitness function, wherein the parameters of genetic operation include mutation probability, crossover probability, and selection method; perform the Genetic Algorithm iteration on the initial population; in a response that the number of genetic iterations is reached, reaches the number of genetic iterations, end the iterating of the Genetic Algorithm; and define the optimal chromosome as a chromosome with a largest fitness value after a last Genetic Algorithm iteration, wherein the fitness value is a value of the chromosome corresponding to the fitness function.

In some examples, the processor unit is further configured to: perform a mutation operation and a crossover operation on the chromosomes of a previous Genetic Algorithm iteration based on the mutation probability and the crossover probability to generate new chromosomes; calculate the fitness value of each of the new chromosomes based on the fitness function; and applying the selection method to the new chromosomes based on the fitness value of each of the new chromosomes, wherein only chromosomes meeting the population size are selected in a present iteration of the Genetic Algorithm.

In some examples, the processor unit is further configured to: set the fitness function based on the objective function of the scheduling model; and decode each of the new chromosomes according to designing rules of the double layer code design to obtain the scheduling scheme corresponding to the new chromosomes; determine an objective function value based on the scheduling scheme; and calculate the fitness value of each of the new chromosomes based on the objective function value and the fitness function.

In some examples, the objective function is related to a completion time of the scheduling scheme, wherein the processor unit is further configured to: split the double layer code design of the chromosomes to obtain a sub-layer workpieces sequence and a batch size corresponding to the chromosomes respectively; match the sequence of the sub-layer workpieces to the batch size to form a batch result; obtain a start time and an operation time of each batch of workpieces according to the process parameters of each batch of workpieces; and according to the sequence of the sub-layer workpieces, schedule the batch results based on a scheduling principle to generate a scheduling scheme corresponding to the chromosomes.

According to a further aspect of the present invention, it provides a computer storage medium having computer programs stored thereon, wherein the computer programs implement the steps of abovementioned batch processing machine scheduling method when the computer programs are executed.

### BRIEF DESCRIPTION OF THE DRAWINGS

The features and advantages of the embodiments of the present disclosure can be better understood in conjunction with the following drawings.

FIG. 1 is a schematic flowchart of a batch processing machine scheduling method according to an embodiment of the present disclosure;

FIG. 2 is a schematic partial flowchart of a batch processing machine scheduling method according to another embodiment of the present disclosure;

FIG. 3 is a schematic partial flowchart of a batch processing machine scheduling method according to another embodiment of the present disclosure;

FIG. 4 is a schematic partial flowchart of a batch processing machine scheduling method according to another embodiment of the present disclosure;

FIG. 5 is a schematic diagram of a chromosome structure according to another embodiment of the present disclosure;

FIG. 6 is a schematic partial flowchart of a batch processing machine scheduling method according to another embodiment of the present disclosure;

FIG. 7 is a schematic partial flowchart of a batch processing machine scheduling method according to another embodiment of the present disclosure;

FIG. 8 is a schematic partial flowchart of a batch processing machine scheduling method according to another embodiment of the present disclosure;

FIG. 9 is a schematic partial flowchart of a batch processing machine scheduling method according to another embodiment of the present disclosure;

FIG. 10 is a schematic block diagram of a batch processing machine scheduling device according to another embodiment of the present disclosure.

### DETAILED DESCRIPTION OF THE APPLICATION

The following description is presented to enable one of ordinary skill in the art to implement and use the present invention and incorporate it into the context of a particular application. Various modifications, as well as various usages in various applications, will be readily apparent to those skilled in the art, and the generic principles defined herein may be applicable to a wide range of embodiments. Thus, the present invention is not limited to the embodiments presented herein, but rather should be given its broadest scope consistent with the principles and novel features disclosed herein.

In the following detailed description, numerous specific details are set forth to provide a more thorough understanding of the present invention. However, it will be apparent to those skilled in the art that the present invention may be practiced without limitations from these specific details. In other words, well known structures and devices are shown in a block diagram form and are not shown in detail, so as to avoid obscuring the present invention.

The contents of all files and documents which are filed at the same time as this specification and which are open for the public are incorporated herein by reference.

Moreover, any component that does not expressly indicate a device having a specific structure or a step for performing a specific function in the claims should not be construed as a device or step clause as specified in 35 USC Chapter 112, paragraph 6. In particular, the use of “steps of . . . ” or “actions of . . . ” in the claims herein does not mean that the provisions of paragraph 6 of 35 USC § 112 are involved.

Note that when used, the arrows left, right, front, back, top, bottom, front, back, clockwise, and counter clockwise are used for convenience purposes only and do not imply any specific fixed direction. In fact, they are used to reflect the relative position and/or direction between various parts of an object. In addition, the terms “first” and “second” are only used for descriptive purposes, and cannot be read as indicating or implying relative importance.

In the description of the present invention, it should be noted that the terms “installation”, “connecting”, and “connected” should be understood broadly unless explicitly stated and defined otherwise. For example, the terms “installation”, “connecting”, and “connected” may be either a fixed connection, a detachable connection, or an integral connection; the terms may be either a mechanical connection or an electrical connection; the terms also may be either a direct connection, an indirect connection through an intermediate medium, or an internal connection between two components. The specific meaning of the above terms in the present invention can be understood in a specific case by those skilled in the art.

Note that in the case of use, further, better, further and more preferably is a simple beginning of another embodiment on the basis of the foregoing embodiment, which is further, better, and further The combination of the content of the ground or the better ground and the foregoing embodiment constitutes a complete composition of another embodiment. After the same embodiment, a number of further, better, further or even better arrangements can be combined to form yet another embodiment.

The present invention will be described in detail below in conjunction with the drawings and specific embodiments. Note that the following aspects described in conjunction with the drawings and specific embodiments are only exemplary, and should not be construed as limiting the protection scope of the present invention.

According to one embodiment of the disclosure, a batch processing machine scheduling method is provided for scheduling a batch processing machine group in a semiconductor factory's production line.

Diffusion furnaces are a type of key machines used in the manufacturing process of semiconductor chips, mainly used for impurity dopant diffusion processes in order to form thin films on the wafers and drive in impurity dopants. To explain the present invention, scheduling process of batch processing furnace machines in film oxidation process on 12-inch semiconductor wafers is chosen as an example.

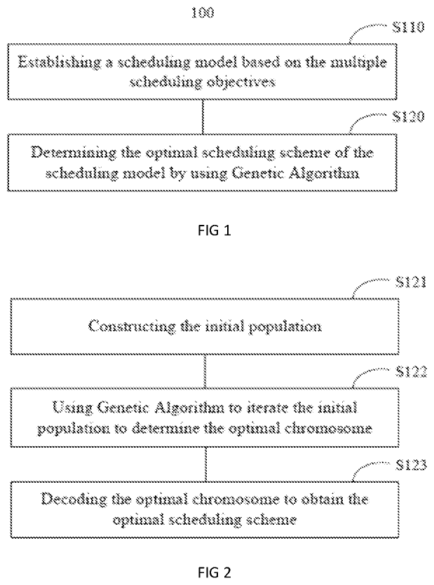

In an embodiment, as shown in FIG. 1, the batch processing machine scheduling method 100 may include steps S110-S120.

Step S110 may include: establishing a scheduling model based on multiple scheduling objectives of multiple batch processing machines and workpieces, wherein the multiple scheduling objectives include meeting the delivery date of the workpieces, improving the capacity utilization rate and batch size of the batch processing machine, and reducing the production cycle of the workpieces.

The delivery date refers to the date when the workpiece is delivered after processing.

Capacity utilization rate refers to the ratio of total workpiece output to production machines, which is the production capacity that actually operates to involve directly in production.

The production cycle of the workpiece includes the time of waiting for operation and the time of operation of the workpiece spent on the machine.

The existing scheduling method of the furnace chamber is divided into two steps: batch combination and batch scheduling. Batch combination applies a certain scheduling rule to form one or more batches by dividing between workpieces sharing the same process parameters and workpieces belonging to different processes. Batch scheduling is to sort all the batches formed in the batch combination step, and select those right for the needed process yet idle machines, and match them for the optimal batch for batch processing.

Therefore, to realize the rational production scheduling of batch processing machine, it is necessary to consider both of the two steps of batch combination and batch scheduling in the scheduling process. That is, the overall quality of the final scheduling result is used as the standard to evaluate the scheduling scheme.

To this end, in connection with the production characteristics and production requirements of batch processing machine, three scheduling objectives have been established, including meeting different delivery dates for a variety of products, increasing the capacity utilization rate and batch size of batch processing machine, and reducing the production cycle of products or workpieces.

However, the three scheduling objectives are mutually restrictive. When achieving optimum one certain scheduling objective, it will undoubtedly sacrifice other scheduling objectives. Therefore, the establishment of the optimal scheduling scheme is to seek the actual comprehensive optimization of the three scheduling objectives.

Specifically, in order to meet the different delivery deadlines of multiple products, Critical Ratio (CR) can be used for hierarchical control. For high-priority workpieces, the capacity utilization rate of the machine is considered last, and the process on the high-priority workpieces must be completed within the specified time; for the low-priority workpieces, the capacity utilization rates of the machines and the production cycles of all workpieces must be considered first.

In order to improve capacity utilization and batch size of the machines, the total number of workpieces contained in the batch that the machines can process has an upper limit and a lower limit. The upper limit determines the maximum number of workpieces put in a batch, which is usually determined by the attributes of the batch processing machine; the lower limit determines the minimum number of workpieces in a batch, and the size of the lower limit is related to the machine occupancy and capacity utilization, so it can be set according to the actual production line conditions, and can be dynamically adjusted according to the actual situation.

In order to reduce the production cycle of products, the batch processing machine may maximize the batch size, that is, the number of products per batch operation reaches the upper limit as much as possible, which can reduce the overall operation time of the products, but may increase the waiting time for some of the products; on the contrary, the shortest waiting time may lead to an increase in operating time.

Therefore, the product production cycle is the ultimate deciding factor of all the above scheduling objectives. When establishing the scheduling model, the reduction of product production cycle can be taken as the objective function, that is, the goal of the scheduling model is to solve the minimum production cycle.

Combining the above description and the various characteristics including the high-capacity design of batch processing machine processing, conditional grouping of operations, long operation time, the realization of double-batch scheduled operations, the various constraints of the scheduling model can be determined, which are described as follows:

(1) The operating time of each workpiece equals to the operating time of this piece on each machine;

(2) Workpieces with the same conditions can be batched as one group;

(3) Workpieces in the same batch are operated on the same machine at the same time;

(4) If a batch of workpieces is already in operation, it cannot be interrupted, and the batch information cannot be changed;

(5) The number of workpieces in each batch has a maximum limit and a minimum limit. The maximum value is determined by the maximum capacity of the machines, and the minimum value is determined by the production requirements, which are all given values;

(6) The operation time of any batch on any machine is equal to the maximum value of the operation time of all workpieces in the batch;

(7) The start time of any batch on any machine is the maximum arrival time among all workpieces in the batch;

(8) The completion time of any batch on any machine is equal to the sum of the start time and the operation time of the batch;

(9) The waiting time of the workpiece with high urgency, that is, the workpiece with high priority at the batch processing site needs to be less than a calculated value, which is the available time allocated to each site from the production cycle of the entire product production line minus a standard operating time; and

(10) Decision variables.

Then, the constraints of the established scheduling model include:

$$\begin{matrix}{\sum }_{b ∈ B} {X}_{jb} = 1 , ∀ j ∈ J , ∀ b ∈ B & ( 1 ) \\ {\sum }_{m ∈ M} {Y}_{bm} = 1 , ∀ b ∈ B , ∀ m ∈ M & ( 2 ) \\ {C}_{b} \geq {C}_{j} {X}_{jb} , ∀ j ∈ J , ∀ b ∈ B & ( 3 ) \\ {R}_{j - 1 , b} = {R}_{jb} , ∀ j ∈ J , ∀ b ∈ B & ( 4 ) \\ {B}_{min} \leq {\sum }_{j ∈ J} {X}_{jb} \leq {B}_{max} , ∀ j ∈ J , ∀ b ∈ B & ( 5 ) \\ {C}_{bm} = {C}_{b} {Y}_{bm} , ∀ b ∈ B , ∀ m ∈ M & ( 6 ) \\ {A}_{bm} \geq {a}_{j} {X}_{jb} {Y}_{bm} , ∀ b ∈ B , ∀ m ∈ M & ( 7 ) \\ {A}_{bm} \geq {F}_{b - 1 , m} , ∀ b ∈ B , ∀ m ∈ M & ( 8 ) \\ {F}_{bm} + {A}_{bm} + {C}_{bm} , ∀ b ∈ B , ∀ m ∈ M & ( 9 ) \\ {WT}_{j} \leq ( {PHL}_{j} \times {DPML}_{j} - Σ {PT}_{j} ) \times \frac{{PT}_{j}}{Σ {PT}_{j}} ( ∀ {CR}_{j} < 1 ) & ( 10 ) \\ {X}_{jb} = \{ 0 , 1 \} , ∀ j ∈ J , ∀ b ∈ B & ( 11 ) \\ {Y}_{bm} = \{ 0 , 1 \} , ∀ b ∈ B , ∀ m ∈ M & ( 12 )\end{matrix}$$

Where, J equals to the number of workpieces, j equals to any one of all the workpieces, Cⱼ is the operating time of any workpiece j, aⱼ is the time of any workpiece j arriving at the batch processing site, Rⱼ is the processing conditions of any workpiece j, B is the total number of batches, b is any set of batches in all batches, C_{b} is the operation time of any batch b, C_{jb} is the operation time of any workpiece j in any batch b, R_{b} is the process condition of any batch b, R_{jb} is the process condition of any workpiece j in any batch b, Bₘₐₓ is the maximum number of workpieces in each batch, Bₘᵢₙ is the minimum number of workpieces in each batch, M is the total number of batch processing machines, m is any batch processing machine among all batch processing machines, C_{bm} is the operating time of the b batch on the m batch processing machine, F_{bm} is the completion time of the b batch on the m batch processing machine, A_{bm} is the start time of the b batch on the m batch processing machine, WTⱼ is the waiting time of workpiece j, PHLⱼ is the number of lithography layers of the current product line j, DPMLⱼ is the allowable lithography time of each layer determined according to the shipment goal of workpiece j, PTⱼ is the standard operating time of product j, CRⱼ is the priority of workpiece j, X_{jb} and Y_{bm} are decision variables.

The above multiple constrained conditions are explained herein. Equation (1) restricts that one workpiece can only be allocated to one batch; equation (2) means that each batch can only be allocated to one machine for operation; equation (3) means that the operation time of each batch is the operation time of the workpiece with the longest operation time in the batch; equation (4) means that the process conditions of all workpieces in each batch are the same; equation (5) means that the number of workpieces in each batch (Batch Size) is within a limited range; equation (6) solves the operation time of each batch on each machine; equation (7) means that the start time of each batch on each machine is greater than or equal to the arrival time of all workpieces in the batch; equation (8) means that the start time of each batch on each machine is greater than or equal to the completion time of the previous batch; equation (9) means that the end time of each batch on each machine is equal to the sum of the start time and the operation time of the batch; equation (10) indicates that the waiting time of the workpieces with CR value less than 1 at the batch processing machine site must meet the shipping requirements of DPMLj, that is, less than a calculated value; equations (11) and (12) are the constrained conditions of decision variables, if the workpiece j is divided into the b batch, X_{jb} equals to 1, otherwise equals to 0; if the b batch is being processed on the m machine, Y_{bm} equals to 1, otherwise equals to 0.

Meanwhile, the objective function of the scheduling model is:

F=min Fₘₐₓ=min(max F_{bm}) (13)

The goal of the scheduling model is to solve the minimum production cycle, that is, the latest completion time among the completion times of all workpieces.

Furthermore, step S120 includes: using a genetic algorithm to determine the optimal scheduling scheme of the scheduling model.

Genetic Algorithms (GA) were presented by Professor J. H. Holland of the University of Michigan in 1975. It was inspired by Darwin's Theory of Evolution and Mendel's Theory of Genetics. By simulating the evolutionary process of natural selection and genetic mechanism, after multiple generations of reproduction, the survival of the fittest of genes is achieved, and the optimal solution is finally searched.

The difficulty of genetic algorithm lies in the process of coding and decoding. The carrier of genetic information is called a chromosome. The chromosome constitutes the candidate solution of the genetic algorithm and is generally presented in the form of binary code, string or data column. The coded solution is called the genotypic solution, and the actual solution is called the phenotypic solution, such as the scheduling scheme in this case. The process of converting phenotypic solutions into genotype solutions is called coding, and the process of converting genotype solutions into phenotypic solutions is called decoding.

Then, the process of using the genetic algorithm to solve the optimal solution of the foregoing scheduling model may specifically include steps S121-S123, as shown in FIG. 2.

Step S121 includes: constructing an initial population based on the parameters of the workpieces and multiple batch processing machines, the initial population includes a number of chromosomes, and each chromosome corresponds to a scheduling scheme.

The parameters of the workpieces and the batch processing machines are the parameters of the workpieces and machines involved in the aforementioned scheduling model.

Constructing the initial population is the process of generating the initial solution. Since the purpose of genetic algorithm is to solve the optimal solution of the aforementioned scheduling model, the initial solution needs to satisfy the aforementioned scheduling model. For this reason, it is necessary to carry out corresponding code design based on the constraints of the scheduling model.

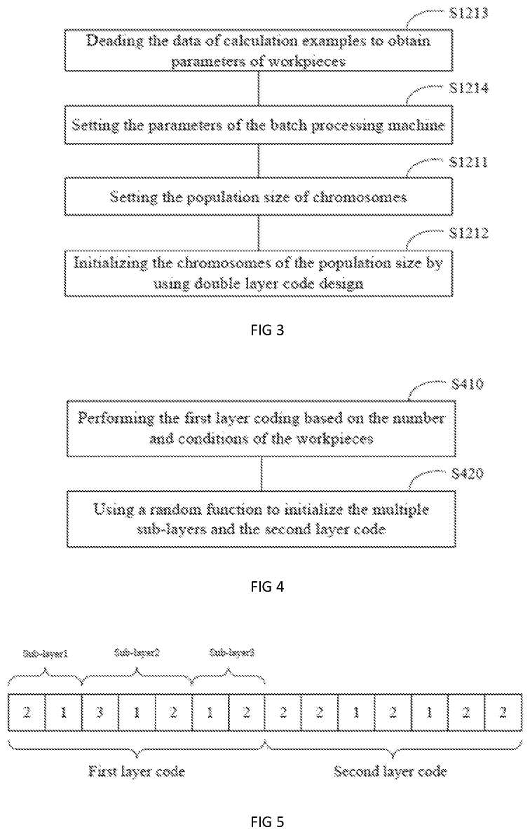

Therefore, in a specific embodiment, as shown in FIG. 3, step S121 may further comprise steps S1211-S1212.

Step S1211 may comprise: setting the size of chromosome population.

Population size refers to the number of chromosomes. The setting of the population size affects the effect of the genetic algorithm. In the case of a larger scale, it will facilitate the combined use of genetic operations, provide sufficient sample capacity for the algorithm, improve the search results of the genetic algorithm, and increase the possibility of obtaining the optimal solution accordingly. However, if the scale exceeds a certain limit, it will increase the amount of calculation of chromosome fitness and reduce the convergence speed of the algorithm. Therefore, the population size can be set according to actual needs.

The population size is generally set between 20 and 200. Preferably, the population size can be set to 200.

Step S1212 may comprise: using the double layer code design to generate the chromosomes of the population size based on the parameters of the workpieces and of the multiple batch processing machines to construct the initial population, and the double layer code design conforms to the scheduling model.

Generating the initial population can generally be divided into two methods. The first is to determine the range of the optimal solution according to the actual problem, and to select and determine the population from this range; the second is to randomly generate a population, select a better chromosome from the randomly generated population as the initial population, and perform repeated iterations so that the initial population that meets the population size is obtained.

Aiming at the characteristics of the batch processing problem, the present invention adopts an improved initial population generation method, that is, a double layer code design to generate the initial population. Specifically, the double layer code includes a first layer code and a second layer code. Among them, the first layer code corresponds to the batch combination results, and the second layer code corresponds to the batch scheduling results. That is, the use of double layer code design satisfies the scheduling model's overall consideration of batch combination and batch scheduling optimization goals.

Preferably, as shown in FIG. 4, step S1212 may include steps S410-S420.

Step S410 may comprise: performing the first layer code based on the number and conditions of the workpieces, the first layer code includes multiple sub-layers, each sub-layer corresponding to one condition. The parameters of the workpieces may include the numbers and the conditions of the workpieces.

The sub-layer design can completely transform the actual scheduling problem into a mathematical problem. When the chromosome is initialized, the first layer sequential code design can be initialized according to the constraints of the number of workpieces and the number of conditions.

Assume that there are a total of j workpieces, the j workpieces have a total of m process conditions, the same conditions can be batched, and the number of workpieces of each condition is ki. Then the length of the first sequential code design is j, which is divided into m-layer sub-code, and the code length of the i-th sub-layer is ki. The gene is a non-repeated sorting integer column of 1˜ki, which indicates the priority order of the batching of workpieces.

Step S420 may include: using a random function to initialize the multiple sub-layers and the second layer code under the constraints of the number and conditions of the multiple batch processing machines. It can ensure the effectiveness and randomness of chromosomes. The parameters of the batch processing machines may include the numbers and the conditions of the batch processing machines.

Corresponding to the above hypothesis, the second layer code is an integer code of length j, and the gene position is an integer from Bmin to Bmax, which represents the size of the batch of each workpiece.

Take an example to illustrate the above-mentioned double layer code design. Assuming j=7, m=3, k1=2, k2=3, and k3=2 in the above hypothesis, then a legal chromosome is shown in FIG. 5.

The first layer of coding corresponds to the access sequence of the workpieces, and the three sub-layers respectively correspond to the three process conditions of the workpieces. Sub-layer 1[2,1] means that the sequence of the workpieces in the first type of condition is 2, 1; sub-layer 2[3,1,2] means that the sequence of the workpieces in the second type of condition is 3, 1, 2, and so on.

The second layer of coding corresponds to the batch size of the workpieces, and its meaning is that the batch size of the first batch is 2, the batch size of the second batch is 2, the batch size of the third batch is 1, and so on.

Furthermore, before constructing the initial population, the step of obtaining various parameters in the scheduling model may also be included.

Specifically, as shown in FIG. 3, step S121 may also include steps S1213-1214.

Step S1213 may include: reading the calculation example data to obtain the workpieces' parameters in the multiple constrained conditions of the scheduling model.

The workpieces' parameters refer to the parameters related to the workpieces, including the workpieces' name, the process conditions of the workpieces, the expected arrival time of the workpieces, the operating time on the batch processing machine, and the CR level and other inherent parameters of the workpieces in the above scheduling model. These parameters can be obtained based on the data of all workpieces that need to be processed in a production process. Generally, the relevant parameters of all workpieces will be stored in the Excel table, and these parameters can be obtained by reviewing the excel table of data examples.

Step S1214 may comprise: setting up parameters of batch processing machine.

The batch processing machine parameters refer to the parameters related to the batch processing machines, specifically including the number of machines in the same group as the machine type and the inherent parameters or setting parameters of the batch processing machines such as the upper and lower limits of the batches that can be processed by these machines. Among them, the upper and lower limits of the batch that the machines can handle are the Bₘᵢₙ and Bₘₐₓ values.

Furthermore, the step S122 in using the genetic algorithm to find the optimal solution is: using the genetic algorithm to perform cyclic iteration on the initial population to determine the optimal chromosome.

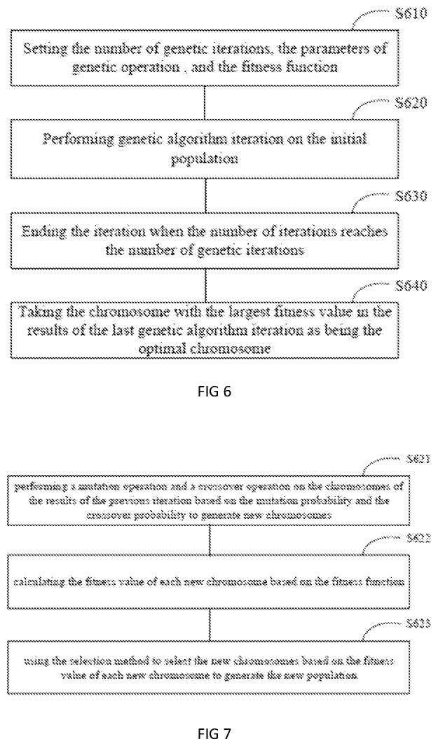

The iterative process of genetic algorithm is the process of genetic operations on the previous generation population to produce a new population. The complete loop iteration process can be shown in FIG. 6, including steps S610-S640.

Step S610 may comprise: setting the number of genetic iterations, genetic operation parameters, and fitness function. The genetic operation parameters include mutation probability, crossover probability, and selection mode.

The number of genetic iterations corresponds to the number of genetic generations of the chromosome population, which can be understood as the number of times to generate a new generation of chromosomes.

Genetic operation mainly includes three forms of crossover, mutation and selection.

Crossover is to imitate the process of sexual reproduction in nature, through the exchange of chromosome segments to produce a new generation of genes. Its purpose is to inherit good genes into the next generation of chromosomes, embodying the principle of information exchange, and is the most effective operation to improve genetic coding.

Mutation is a method of randomly changing the gene value on one or more chromosomes with a certain probability to produce new chromosomes. Mutation can effectively supplement the gene characteristics lost during selection and crossover.

Selection is the operation of selecting good individuals from the current population to directly enter the next generation population.

According to the characteristics of the above-mentioned double layer code design, the present invention adopts a two-point mutation method and a two-point crossover method for the genetic operators in the first layer code. Preferably, after the crossover, the complement of the crossover segment can also be randomly arranged to the non-crossover segment for chromosome repair. Further, for the genetic operators in the second layer code, the single-point mutation method and the two-point crossover method are used to perform genetic operations.

Fitness refers to the performance of a single chromosome or the degree of adaptation to the environment. It determines the search direction of the solution and directly affects the quality and search efficiency of the final solution. The fitness function is used to find the fitness of each chromosome. The fitness is generally positive. The greater the fitness value of the chromosome, the higher the fitness and the easier it is to be selected for the next genetic operation to generate a new generation of chromosomes. For the established mathematical model, the objective function is usually directly used as the fitness function. In the multi-objective optimization problem, firstly, the multi-objective should be normalized and transformed into a single-objective problem, or the scheduling objective should be reflected in the constrained conditions. Preferably, in the process of determining the furnace chamber machine scheduling scheme, the reciprocal of the objective function of the furnace chamber machine scheduling model can be set as the fitness function.

Preferably, the above-mentioned selection operation can use the roulette selection method to select according to the fitness values of the chromosomes to establish a new round of population.

Roulette selection method is also called fitness value ratio method or Monte Carlo model. Its basic principle is to first find the sum of the fitness of all chromosomes, and the probability of each chromosome being selected is value whose fitness occupies the sum of the fitness of all chromosomes. The higher the proportion of chromosomes with higher fitness, the higher the probability of being selected, and vice versa, the lower the probability of being selected, which reflects the natural selection law of survival of the fittest.

In the initial stage of genetic algorithm, at least the population size, number of iterations, crossover probability and mutation probability need to be set. The value of these parameters directly affects the search efficiency of the genetic algorithm and the quality of the solution. The empirical value of these parameters can be obtained through preliminary experiments and other work in the early stage, and the empirical value of each parameter corresponding to the actual problem is taken in the initial stage of the genetic algorithm. Preferably, in the process of determining the furnace chamber machine scheduling scheme, the population size can be set to 200, the number of iterations to 400, the mutation probability to 0.05, and the crossover probability to 0.8.

Step S620 may comprise: performing genetic algorithm iteration on the initial population.

After setting the parameters in early stage, the genetic algorithm can be used for loop iteration.

Each iteration process is the process of generating a new generation of population. The specific steps of each iteration can be shown in FIG. 7, including steps S621-S623.

Step S621 may comprise: performing a mutation operation and a crossover operation on the chromosomes of the results of a previous genetic algorithm iteration based on the mutation probability and the crossover probability to generate new chromosomes.

Specifically, as described before, according to the double layer code design of the present invention, for the first layer of chromosomes, the mutation operation adopts a two-point mutation method, and the crossover operation adopts a two-point crossover method; for the second layer of coding, the mutation operation uses the single-point mutation method and the crossover operation uses two-point crossover method to perform genetic operations.

Preferably, before performing the mutation operation and the crossover operation, it is also possible to assign a fitness value to each chromosome according to the fitness value calculated for each chromosome in the previous iteration process. The higher the fitness of the chromosome, the higher the probability of being selected in the mutation operation and crossover operation.

Step S622 may comprise: calculating the fitness value of each new chromosome based on the fitness function.

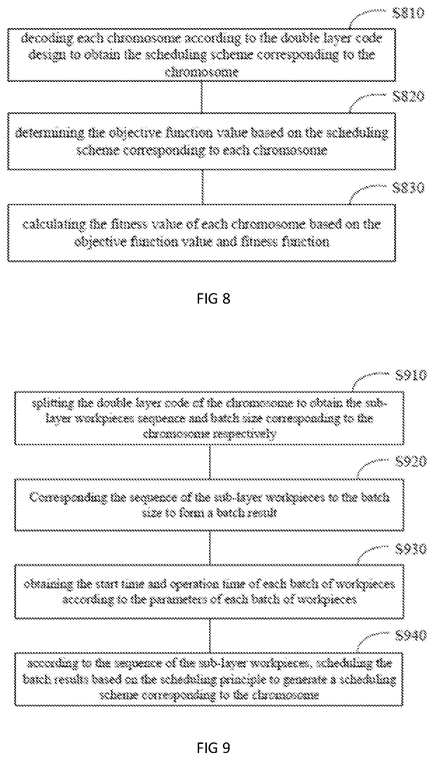

The present invention is based on the characteristics of the scheduling model of the batch processing machine, and uses the reciprocal of the objective function in the scheduling model as the fitness function. Therefore, in order to calculate the fitness value of each chromosome, it is also necessary to determine the objective function of the scheduling scheme corresponding to each chromosome. Specifically, as shown in FIG. 8, to determine the fitness value of each new chromosome, steps S810-S830 may be included.

Step S810 may comprise: decoding each chromosome according to the rules of the double layer code design to obtain the scheduling scheme corresponding to the chromosome.

The internal decoding process of the genetic algorithm is internally closed, and does not and does not need to output the decoding result of each chromosome. The specific decoding process will be described in detail in the decoding process of the optimal chromosome in step S123.

Step S820 may comprise: determining the objective function value based on the scheduling scheme.

Determine the maximum completion time among the completion times of all workpieces according to the scheduling scheme after each chromosome is decoded, that is, the production period of the scheduling scheme corresponding to the decoded chromosome, that is, the objective function value corresponding to the chromosome.

Step S830 may comprise: calculating the fitness value of the chromosome based on the objective function value and the fitness function.

The ranking function of the genetic algorithm toolbox can be used to calculate the fitness value based on the value of the objective function. The essence of the sorting function is to sort the list according to the value of the objective function from large to small, and return the pressure difference column vector containing the corresponding chromosome. The pressure difference is the difference in the fitness value of the assigned chromosome, reflecting the difference between the best and the worst. The pros and cons of chromosomes can be distinguished based on the pressure difference to make selections.

Further, the specific selection step S623 may comprise: using the set selection method to select the new chromosomes based on the fitness value of each new chromosome until the selected chromosomes meet the population size number of chromosomes, taking those selected chromosomes as the results of present iteration of the genetic algorithm.

Specifically, according to the fitness value vector, the roulette selection method is used to randomly obtain a chromosome according to the probability, which is used to establish a new round of population. The selection is stopped until the selected chromosomes meet the population size number of chromosomes, and this round of iteration ends.

Further, step S630 may comprise: when the number of iterations reaches the number of genetic iterations, stop the iteration of the genetic algorithm.

The optimal chromosome is selected from the population generated in the last iteration. Specifically, step S640 may comprise: taking the chromosome with the largest fitness value in the results of the last genetic algorithm iteration as the optimal chromosome.

After the optimal chromosome is determined, the scheduling scheme corresponding to the optimal chromosome can be determined by decoding. That is, step S123 may comprise: decoding the optimal chromosome to obtain a scheduling scheme corresponding to the optimal chromosome as the optimal scheduling scheme.

Specifically, FIG. 9 shows the decoding process of a single chromosome. As shown in FIG. 9, the decoding process includes steps S910-S940.

Step S910 may comprise: splitting the double layer code of the chromosome to obtain the sub-layer workpieces sequence and batch size corresponding to the chromosome.

The chromosome is first split into the first layer genome and the second layer genome based on the rules of double layer code. Based on the first layer code rules, the first layer genome is further divided into m-layer sub-layers corresponding to the number m of process conditions of the workpieces. Each sub-layer includes several ordered workpieces with the same process conditions, and the m-layer sub-layer includes a total of j workpieces. Based on the second layer code rules, the second layer genome is split into batch sizes.

Taking the chromosome shown in FIG. 5 as an example, the first layer genome is split into three sub-layers, and sub-layer 1 is taken as an example for the first genome decoding description. The sub-layer 1 includes 2 workpieces. Assuming that the 2 workpieces can correspond to two workpieces A and B of the 7 workpieces, the numbers of the workpieces A and B in the sub-layer 1 are 1, 2 respectively. According to the workpieces order [2, 1] of sub-layer 1, the processing order of the workpieces A and B should be B first and then A. The results of the second layer genome splitting are: 2, 2, 1 . . . Then the size of the first batch is 2, the size of the second batch is 2, and the size of the third batch is 1 . . .

Step S920 may comprise: corresponding the sub-layer workpieces sequence according to the batch size to form a batch result.

Take sub-layer 1 in FIG. 5 as an example for group batch description. The batch results of the two workpieces in the sub-layer 1 need to be matched according to the batch size of the second layer genome. After the second layer of genome is split, the first gene is 2, that is, the batch size of the first batch is 2, and sub-layer 1 happens to include 2 workpieces, so the 2 workpieces A and B in sub-layer 1 compose the first batch. It can be understood that if the number of workpieces in the sub-layer 1 exceeds the corresponding batch size, the workpieces in the sub-layer 1 will form multiple batches according to their processing order.

Step S930 may comprise: obtaining the start time and operation time of each batch of workpieces according to the parameter information of each batch of workpieces.

In the aforementioned steps of obtaining workpieces' parameters, the estimated arrival time and operation time of each workpiece can be obtained. In combination with the constrained conditions of the aforementioned scheduling model, the start time of each batch is equal to the latest expected arrival time of all workpieces in the batch, and the operation time of each batch is equal to the maximum operation time of all workpieces in the batch.

Step S940 may comprise: according to the sequence of the sub-layer workpieces, scheduling the batch results based on the scheduling principle to generate a scheduling scheme corresponding to the chromosome.

According to the code sequence, the batch results will be scheduled according to the first-in first-out principle.

It can be understood that the completion time of the batch can be determined by combining the start time and operation time of each batch, and the working time and idle time of each batch processing machine can be determined based on the completion time of each batch, then assigning the operation batches to each batch processing machine. Finally, the completion time of all batches and the operating time of all batch processing machines can be determined. Among them, the maximum value of the completion time of all batches is the objective function value.

Furthermore, after the optimal scheduling scheme is determined by the genetic algorithm, the batch processing machine scheduling method further includes: scheduling all the workpieces to the batch processing machine for processing based on the determined optimal scheduling scheme.

Although the method is illustrated and described as a series of actions for the purpose of simplifying the explanation, it should be understood and appreciated that these methods are not limited by the sequence of the actions. Those skilled in the art may understand that some actions may occur in different orders and/or concurrently with other actions that are illustrated and described herein or that are not illustrated and described herein, in accordance with one or more embodiments.

According to another aspect of the present invention, a computer storage medium which stores computer programs is provided, wherein the computer programs implement the steps of the batch processing machine scheduling method of foregoing embodiments when the computer programs are executed.

According to another aspect of the present invention, a batch processing machine scheduling device is also provided, which is suitable for the scheduling of workpieces of multiple batch processing machines, and is particularly suitable for the scheduling of batch processing machine groups on a semiconductor production line.

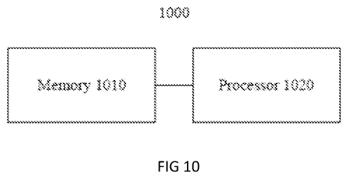

In an embodiment, as shown in FIG. 10, the batch processing machine scheduling device 1000 includes a memory unit 1010 and a processor unit 1020.

Memory unit 1010 stores computer programs.

The processor unit 1020 is coupled to the memory unit 1010, and is configured to execute the computer programs on the memory unit 1010. The processor unit is configured to: establish a scheduling model based on multiple scheduling objectives of the multiple batch processing machines and the workpieces, wherein the multiple scheduling objectives include meeting the delivery date of the workpieces, improving the capacity utilization rate and batch size of the batch processing machine, and reducing the production cycle of the workpieces; and use Genetic Algorithm to determine the optimal scheduling scheme of the scheduling model.

The delivery date refers to the date when the workpiece is delivered after processing.

Capacity utilization rate refers to the ratio of total output to production machine, which is the production capacity that actually operates to play a role in production.

The production cycle of the workpiece includes the time of waiting for operation and the time of operation.

The existing scheduling method of the furnace chamber is divided into two steps: batch combination and batch scheduling. Batch combination is to use a certain scheduling rule to form one or more batches between workpieces of the same process parameter and workpieces of different processing types. Batch scheduling is to sort all the batches formed in the batch combination step, and select the corresponding idle machine and the optimal batch for batch processing.

Therefore, to realize the rational production scheduling of batch processing machine, it is necessary to consider both the two steps of batch combination and batch scheduling in the scheduling process. That is, the overall quality of the final scheduling result is used as the standard to evaluate the scheduling scheme.

To this end, in connection with the production characteristics and production requirements of batch processing machine, three scheduling objectives have been established, including meeting different delivery dates for a variety of products, increasing the capacity utilization rate and batch size of batch processing machine, and reducing the production cycle of products or workpieces.

However, the three scheduling objectives are mutually restrictive. When achieving optimum one certain scheduling objective, it will undoubtedly necessary sacrifice other scheduling objectives. Therefore, the establishment of the optimal scheduling scheme is actually to seek the comprehensive optimization of the three scheduling objectives.

Specifically, in order to meet the different delivery deadlines of multiple products, CR can be used for hierarchical control. For high-priority workpieces, the capacity utilization rate of the machine is considered last, and the process on the high-priority workpieces must be completed within the specified time; for the low-priority workpieces, the capacity utilization rate of the machine and the production cycle of all workpieces must be considered first.

In order to improve capacity utilization and batch size of the machines, the number of workpieces contained in the batch that the machines can process has an upper limit and a lower limit. The upper limit determines the maximum number of workpieces in a batch, which is usually determined by the attributes of the batch processing machine; the lower limit determines the minimum number of workpieces in a batch, and the size of the lower limit is related to the machine occupancy and capacity utilization, so it can be set according to the actual production line conditions, and can be dynamically adjusted according to the actual situation.

In order to reduce the production cycle of products, the batch processing machine may maximize the batch size, that is, the number of products per batch operation reaches the upper limit as much as possible, which can reduce the overall operation time of the products, but may increase the waiting time for the products; on the contrary, the shortest waiting time may lead to an increase in operating time.

Therefore, the product production cycle is the ultimate carrier of all the above scheduling objectives. When establishing the scheduling model, the reduction of product production cycle can be taken as the objective function, that is, the goal of the scheduling model is to solve the minimum production cycle.

Combining the above description and the various characteristics including the high-capacity design of batch processing machine processing, conditional grouping of operations, long operation time, the realization of double-batch scheduled operations, the various constraints of the scheduling model can be determined, which are described respectively as follows:

(1) The operating time of each workpiece equals to the operating time of this piece on each machine;

(2) Workpieces having the same conditions can be batched as one group;

(3) Workpieces in the same batch are operated on the same machine at the same time;

(4) If a batch of workpieces is already in operation, it cannot be interrupted, and the batch information cannot be changed;

(5) The number of workpieces in each batch has a maximum limit and a minimum limit. The maximum value is determined by the maximum capacity of the machines, and the minimum value is determined by the production requirements, which are all given values;

(6) The operation time of any batch on any machine is equal to the maximum value of the operation time of all workpieces in the batch;

(7) The start time of any batch on any machine is the maximum arrival time of all workpieces in the batch;

(8) The completion time of any batch on any machine is equal to the sum of the start time and the operation time of the batch;

(9) The waiting time of the workpiece with high urgency, that is, the workpiece with high priority, at the batch processing site needs to be less than a calculated value, which is the available time allocated to each site from the production cycle of the entire product production line minus a standard operating time; and

(10) Decision variables.

Then, the constraints of the established scheduling model include:

$$\begin{matrix}{\sum }_{b ∈ B} {X}_{jb} = 1 , ∀ j ∈ J , ∀ b ∈ B & ( 1 ) \\ {\sum }_{m ∈ M} {Y}_{bm} = 1 , ∀ b ∈ B , ∀ m ∈ M & ( 2 ) \\ {C}_{b} \geq {C}_{j} {X}_{jb} , ∀ j ∈ J , ∀ b ∈ B & ( 3 ) \\ {R}_{j - 1 , b} = {R}_{jb} , ∀ j ∈ J , ∀ b ∈ B & ( 4 ) \\ {B}_{min} \leq {\sum }_{j ∈ J} {X}_{jb} \leq {B}_{max} , ∀ j ∈ J , ∀ b ∈ B & ( 5 ) \\ {C}_{bm} = {C}_{b} {Y}_{bm} , ∀ b ∈ B , ∀ m ∈ M & ( 6 ) \\ {A}_{bm} \geq {a}_{j} {X}_{jb} {Y}_{bm} , ∀ b ∈ B , ∀ m ∈ M & ( 7 ) \\ {A}_{bm} \geq {F}_{b - 1 , m} , ∀ b ∈ B , ∀ m ∈ M & ( 8 ) \\ {F}_{bm} + {A}_{bm} + {C}_{bm} , ∀ b ∈ B , ∀ m ∈ M & ( 9 ) \\ {WT}_{j} \leq ( {PHL}_{j} \times {DPML}_{j} - Σ {PT}_{j} ) \times \frac{{PT}_{j}}{Σ {PT}_{j}} ( ∀ {CR}_{j} < 1 ) & ( 10 ) \\ {X}_{jb} = \{ 0 , 1 \} , ∀ j ∈ J , ∀ b ∈ B & ( 11 ) \\ {Y}_{bm} = \{ 0 , 1 \} , ∀ b ∈ B , ∀ m ∈ M & ( 12 )\end{matrix}$$

Where, J means the number of workpieces, j means any one of all the workpieces, Cⱼ is the operating time of any workpiece j, aⱼ is the time of any workpiece j arriving at the batch processing site, Rⱼ is the processing conditions of any workpiece j, B is the total number of batches, b is any set of batches in all batches, C_{b} is the operation time of any batch b, C_{jb} is the operation time of any workpiece j in any batch b, R_{b} is the process condition of any batch b, R_{jb} is the process condition of any workpiece j in any batch b, Bₘₐₓ is the maximum number of workpieces in each batch, Bₘᵢₙ is the minimum number of workpieces in each batch, M is the total number of batch processing machines, m is any batch processing machine among all batch processing machines, C_{bm} is the operating time of the b batch on the m batch processing machine, F_{bm} is the completion time of the b batch on the m batch processing machine, A_{bm} is the start time of the b batch on the m batch processing machine, WTⱼ is the waiting time of workpiece j, PHLⱼ is the number of lithography layers of the current product line j, DPMLⱼ is the allowable lithography time of each layer determined according to the shipment goal of workpiece j, PTⱼ is the standard operating time of product j, CRⱼ is the priority of workpiece j, X_{jb} and Y_{bm} are decision variables.

The above multiple constrained conditions are explained herein. Equation (1) restricts that one workpiece can only be allocated to one batch; equation (2) means that each batch can only be allocated to one machine for operation; equation (3) means that the operation time of each batch is the operation time of the workpiece with the longest operation time in the batch; equation (4) means that the process conditions of all workpieces in each batch are the same; equation (5) means that the number of workpieces in each batch (Batch Size) is within a limited range; equation (6) solves the operation time of each batch on each machine; equation (7) means that the start time of each batch on each machine is greater than or equal to the arrival time of all workpieces in the batch; equation (8) means that the start time of each batch on each machine is greater than or equal to the completion time of the previous batch; equation (9) means that the end time of each batch on each machine is equal to the sum of the start time and the operation time of the batch; equation (10) indicates that the waiting time of the workpieces with CR value less than 1 at the batch processing machine site must meet the shipping requirements of DPMLj, that is, less than a calculated value; equations (11) and (12) are the constrained conditions of decision variables, if the workpiece j is divided into the b batch, X_{jb} equals to 1, otherwise equals to 0; if the b batch is being processed on the m machine, Y_{bm} equals to 1, otherwise equals to 0.

Meanwhile, the objective function of the scheduling model is:

F=min Fₘₐₓ=min(max F_{bm}) (13)

The goal of the scheduling model is to solve the minimum production cycle, that is, the latest completion time among the completion times of all workpieces.

Furthermore, step S120 includes: using a genetic algorithm to determine the optimal scheduling scheme of the scheduling model.

Genetic Algorithm (GA) was presented by Professor J. H. Holland of the University of Michigan in 1975. It was inspired by Darwin's Theory of Evolution and Mendel's Theory of Genetics. By simulating the evolutionary process of natural selection and genetic mechanism, after multiple generations of reproduction, the survival of the fittest of genes is achieved, and the optimal solution is finally searched.

The difficulty of genetic algorithm lies in the process of coding and decoding. The carrier of genetic information is called a chromosome. The chromosome constitutes the candidate solution of the genetic algorithm and is generally presented in the form of binary code, string or data column. The coded solution is called the genotypic solution, and the actual solution is called the phenotypic solution, such as the scheduling scheme in this case. The process of converting phenotypic solutions into genotype solutions is called coding, and the process of converting genotype solutions into phenotypic solutions is called decoding.

Then, in order to realize the process of using the genetic algorithm to solve the optimal solution of the foregoing scheduling model, the processor unit 1020 also comprises: constructing an initial population based on the parameters of the workpieces and of the multiple batch processing machines, the initial population includes a number of chromosomes, and each chromosome corresponds to a scheduling scheme that satisfies the scheduling model; using a genetic algorithm to iterate the initial population to determine the optimal chromosome; and decoding the optimal chromosome to obtain a scheduling scheme corresponding to the optimal chromosome as the optimal scheduling scheme.

The parameters of the workpieces and the batch processing machines are the parameters of the workpieces and machines involved in the aforementioned scheduling model.

Constructing the initial population is the process of generating the initial solution. Since the purpose of genetic algorithm is to solve the optimal solution of the aforementioned scheduling model, the initial solution needs to satisfy the aforementioned scheduling model. For this reason, it is necessary to carry out corresponding code design based on the constraints of the scheduling model.

Therefore, in order to construct the initial population, the processor unit 1020 is further configured to: set the chromosome population size, and use the double layer code design to generate the chromosomes of the population size based on the parameters of the workpieces and of the multiple batch processing machines to construct the initial population, and the double layer code design conforms to the scheduling model.

Population size refers to the number of chromosomes. The setting of the population size affects the effect of the genetic algorithm. In the case of a larger scale, it will facilitate the combined use of genetic operations, provide sufficient sample capacity for the algorithm, improve the search results of the genetic algorithm, and increase the possibility of obtaining the optimal solution accordingly. However, if the scale exceeds a certain limit, it will increase the amount of calculation of chromosome fitness and reduce the convergence speed of the algorithm. Therefore, the population size can be set according to actual needs.

The population size is generally set between 20 and 200. Preferably, the population size can be set at 200.

Generating the initial population can generally be divided into two methods. The first is to determine the range of the optimal solution according to the actual problem, and to select and determine the population from this range; the second is to randomly generate a population, select a better chromosome from the randomly generated population as the initial population, and perform repeated iterations so that the initial population that meets the population size is obtained.

Aiming at the characteristics of the batch processing problem, the present invention adopts an improved initial population generation method, that is, a double layer code design to generate the initial population. Specifically, double layer code includes a first layer code and a second layer code. Among them, the first layer code corresponds to the batch combination results, and the second layer code corresponds to the batch scheduling results. That is, the use of double layer code design satisfies the scheduling model's overall consideration of batch combination and batch scheduling optimization goals.

Preferably, the processor unit 1020 is further configured to: perform the first layer code based on the number and conditions of the workpieces, the first layer code includes multiple sub-layers, each sub-layer corresponding to one condition; and use a random function to initialize the multiple sub-layers and the second layer code under the constraints of the number and conditions of the multiple batch processing machines. The parameters of the workpieces may include the numbers and the conditions of the workpieces. The parameters of the batch processing machines may include the numbers and the conditions of the batch processing machines.

The sub-layer design can completely transform the actual scheduling problem into a mathematical problem. When the chromosome is initialized, the first layer sequential code design can be initialized according to the constraints of the number of workpieces and the number of conditions.

Assume that there are a total of j workpieces, the j workpieces have a total of m process conditions, the same conditions can be batched, and the number of workpieces of each condition is ki. Then the length of the first sequential code design is j, which is divided into m-layer sub-code, and the code length of the i-th sub-layer is ki. The gene is a non-repeated sorting integer column of 1˜ki, which indicates the priority order of the batching of workpieces.

Corresponding to the above hypothesis, the second layer code is an integer code of length j, and the gene position is an integer from Bmin to Bmax, which represents the size of the batch of each workpiece.

Take an example to illustrate the above-mentioned double layer code design. Assuming j=7, m=3, k1=2, k2=3, and k3=2 in the above hypothesis, then a legal chromosome is shown in FIG. 5.

The first layer of code corresponds to the access sequence of the workpieces, and the three sub-layers respectively correspond to the three process conditions of the workpieces. Sub-layer 1[2,1] means that the sequence of the workpieces in the first type of condition is 2, 1; sub-layer 2[3,1,2] means that the sequence of the workpieces in the second type of condition is 3, 1, 2, and so on.

The second layer of code corresponds to the batch size of the workpieces, and its meaning is that the batch size of the first batch is 2, the batch size of the second batch is 2, the batch size of the third batch is 1, and so on.

Furthermore, before constructing the initial population, various parameters in the scheduling model need to be obtained. The processor unit 1020 is further configured to: read the calculation example data to obtain the workpieces' parameters in the multiple constrained conditions of the scheduling model; and set parameters of batch processing machine.

The workpieces' parameters refer to the parameters related to the workpiece, including the workpieces' name, the process conditions of the workpieces, the expected arrival time of the workpiece, the operating time on the batch processing machine, and the CR level and other inherent parameters of the workpiece in the above scheduling model. These parameters can be obtained based on the data of all workpieces that need to be processed in a production process. Generally, the relevant parameters of all workpieces will be stored in the Excel table, and these parameters can be obtained by reading the example data in the excel table.

The batch processing machine parameters refer to the parameters related to the batch processing machine, specifically including the number of machines corresponding to the machine type and the inherent parameters or setting parameters of the batch processing machine such as the upper and lower limits of batches that can be processed by the machines. Among them, the upper and lower limits of the batch that the machines can handle are the Bmin and Bmax values.

Furthermore, the iterative process of genetic algorithm is the process of genetic operations on the previous generation population to produce a new population. Correspondingly, the processor unit 1020 is further configured to set the number of genetic iterations, genetic operation parameters, and fitness function. The genetic operation parameters include mutation probability, crossover probability, and selection mode; The processor unit 1020 is further configured to perform genetic algorithm iteration on the initial population; when the number of iterations reaches the number of genetic iterations, end the iteration of the genetic algorithm; and take the chromosome with the largest fitness value in the results of the last genetic algorithm iteration as being the optimal chromosome.

The number of genetic iterations corresponds to the number of genetic generations of the chromosome population, which can be understood as the number of times to generate a new generation of chromosomes.

Genetic operation mainly includes three forms of crossover, mutation and selection.

Crossover is to imitate the process of sexual reproduction in nature, through the exchange of chromosome segments to produce a new generation of genes. Its purpose is to inherit good genes into the next generation of chromosomes, embodying the principle of information exchange, and is the most effective operation to improve genetic coding.

Mutation is a method of randomly changing the gene value on one or more chromosomes with a certain probability to produce new chromosomes. Mutation can effectively supplement the gene characteristics lost during selection and crossover.

Selection is the operation of selecting good individuals from the current population to directly enter the next generation population.

According to the characteristics of the above-mentioned double layer code design, the present invention adopts a two-point mutation method and a two-point crossover method for the genetic operators in the first layer code. Preferably, after the crossover, the complement of the crossover segment can also be randomly arranged to the non-crossover segment for chromosome repair. Further, for the genetic operators in the second layer code, the single-point mutation method and the two-point crossover method are used to perform genetic operations.

Fitness refers to the performance of a single chromosome or the degree of adaptation to the environment. It determines the search direction of the solution and directly affects the quality and search efficiency of the final solution. The fitness function is used to find the fitness of each chromosome. The fitness is generally positive. The greater the fitness value of the chromosome, the higher the fitness and the easier it is to be selected for the next genetic operation to generate a new generation of chromosomes. For the established mathematical model, the objective function is usually directly used as the fitness function. In the multi-objective optimization problem, firstly, the multi-objective should be normalized and transformed into a single-objective problem, or the scheduling objective should be reflected in the constrained conditions. Preferably, in the process of determining the furnace chamber machine scheduling scheme, the reciprocal of the objective function of the furnace chamber machine scheduling model can be set as the fitness function.

Preferably, the above-mentioned selection operation can use the roulette selection method to select according to the fitness values of the chromosomes to establish a new round of population.

Roulette selection method is also called fitness value ratio method or Monte Carlo model. Its basic principle is to first find the sum of the fitness of all chromosomes, and the probability of each chromosome being selected is value whose fitness occupies the sum of the fitness of all chromosomes. The higher the proportion of chromosomes with higher fitness, the higher the probability of being selected, and vice versa, the lower the probability of being selected, which reflects the natural selection law of survival of the fittest.

In the initial stage of genetic algorithm, at least the population size, number of iterations, crossover probability and mutation probability need to be set. The value of these parameters directly affects the search efficiency of the genetic algorithm and the quality of the solution. The empirical value of these parameters can be obtained through preliminary experiments and other work in the early stage, and the empirical value of each parameter corresponding to the actual problem is taken in the initial stage of the genetic algorithm. Preferably, in the process of determining the furnace chamber machine scheduling scheme, the population size can be set to 200, the number of iterations to 400, the mutation probability to 0.05, and the crossover probability to 0.8.

After setting the parameters in early stage, the genetic algorithm can be used for loop iteration.

Each iteration process is a process of generating a new generation of population. Correspondingly, the processor unit 1020 is further configured to: perform a mutation operation and a crossover operation on the chromosomes of the results of a former genetic algorithm iteration based on the mutation probability and the crossover probability to generate new chromosomes; calculate the fitness value of each new chromosome based on the fitness function; and use the selection method to select the new chromosomes based on the fitness value of each new chromosome until the selected chromosomes meet the population size number of chromosomes, take those selected chromosomes as being the results of present iteration of the genetic algorithm.

Specifically, as described before, according to the double layer code design of the present invention, for the first layer of chromosomes, the mutation operation adopts a two-point mutation method, and the crossover operation adopts a two-point crossover method; for the second layer of encoding, the mutation operation uses the single-point mutation method and the crossover operation uses two-point crossover method to perform genetic operations.

Preferably, before performing the mutation operation and the crossover operation, it is also possible to assign a fitness value to each chromosome according to the fitness value calculated for each chromosome in the previous iteration process. The higher the fitness of the chromosome, the higher the probability of being selected in the mutation operation and crossover operation.

The present invention is based on the characteristics of the scheduling model of the batch processing machine, and uses the reciprocal of the objective function in the scheduling model as the fitness function. Therefore, in order to calculate the fitness value of each chromosome, it is also necessary to determine the objective function of the scheduling scheme corresponding to each chromosome. Specifically, in order to determine the fitness value of each new chromosome, the processor unit 1020 is further configured to: decode each chromosome according to the designing rules of the double layer code to obtain the scheduling scheme corresponding to the chromosome; determine the objective function value based on the scheduling scheme; and calculate the fitness value of each chromosome based on the objective function value and fitness function.

The internal decoding process of the genetic algorithm is internally closed, and does not and does not need to output the decoding results of each chromosome.

Determine the maximum completion time among the completion times of all workpieces according to the scheduling scheme after each chromosome is decoded, that is, the production period of the scheduling scheme corresponding to the decoded chromosome, that is, the objective function value corresponding to the chromosome.

The ranking function of the genetic algorithm toolbox can be used to calculate the fitness value based on the value of the objective function. The essence of the sorting function is to sort the list according to the value of the objective function from large to small, and return the pressure difference column vector containing the corresponding chromosome. The pressure difference is the difference in the fitness value of the assigned chromosome, reflecting the difference between the best and the worst. The pros and cons of chromosomes can be distinguished based on the pressure difference to make selections.

Furthermore, according to the fitness value vector, the roulette selection method is used to randomly obtain a chromosome according to the probability, which is used to establish a new round of population. The selection is stopped until the selected chromosomes met the population size number of chromosomes, and this round of iteration ends.

The optimal chromosome is selected from the population generated in the last iteration.

After the optimal chromosome is determined, the scheduling scheme corresponding to the optimal chromosome can be determined by decoding.

In order to realize the decoding of a single chromosome, the processor unit 1020 is further configured to: split the double layer code of the chromosome to obtain the sub-layer workpieces sequence and batch size corresponding to the chromosome respectively; choose the sequence of the sub-layer workpieces corresponding to the batch size to form a batch result; obtain the start time and operation time of each batch of workpieces according to the parameters of each batch of workpieces, and according to the sequence of the sub-layer workpieces, schedule the batch results based on the scheduling principle to generate a scheduling scheme corresponding to the chromosome.

The chromosome is first split into the first layer genome and the second layer genome based on the rules of double layer code. Based on the first layer code rules, the first layer genome is further divided into m-layer sub-layers corresponding to the number m of process conditions of the workpieces. Each sub-layer includes several ordered workpieces with the same process conditions, and the m-layer sub-layer includes a total of j workpieces. Based on the second layer code rules, the second layer genome is split into batch sizes.

Taking the chromosome shown in FIG. 5 as an example, the first layer genome is split into three sub-layers, and sub-layer 1 is taken as an example for the first genome decoding description. The sub-layer 1 includes 2 workpieces. Assuming that the 2 workpieces can correspond to two workpieces A and B of the 7 workpieces, the numbers of the workpieces A and B in the sub-layer 1 are 1, 2 respectively. According to the workpieces order [2, 1] of sub-layer 1, the processing order of the workpieces A and B should be B first and then A. The results of the second layer genome splitting are: 2, 2, 1 . . . Then the size of the first batch is 2, the size of the second batch is 2, and the size of the third batch is 1 . . .

Take sub-layer 1 in FIG. 5 as an example for group batch description. The batch results of the two workpieces in the sub-layer 1 need to be matched according to the batch size of the second layer genome. After the second layer of genome is split, the first gene is 2, that is, the batch size of the first batch is 2, and sub-layer 1 happens to include 2 workpieces, so the 2 workpieces A and B in sub-layer 1 compose the first batch. It can be understood that if the number of workpieces in the sub-layer 1 exceeds the corresponding batch size, the workpieces in the sub-layer 1 will form multiple batches according to their processing order.

In the aforementioned steps of obtaining workpieces' parameters, the estimated arrival time and operation time of each workpiece can be obtained. In combination with the constrained conditions of the aforementioned scheduling model, the start time of each batch is equal to the latest expected arrival time of all workpieces in the batch, and the operation time of each batch is equal to the maximum operation time of all workpieces in the batch.

According to the code sequence, the batch results will be scheduling according to the first-in first-out principle.

It can be understood that the completion time of the batch can be determined by combining the start time and operation time of each batch, and the working time and idle time of each batch processing machine can be determined based on the completion time of each batch, then assigning the operation batches to each batch processing machine. Finally, the completion time of all batches and the operating time of all batch processing machines can be determined. Among them, the maximum value of the completion time of all batches is the objective function value.

Furthermore, after the optimal scheduling scheme is determined by the genetic algorithm, the processor unit 1020 is also configured to: schedule all the workpieces to the batch processing machine for processing based on the determined optimal scheduling scheme.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor unit, a digital signal processor unit (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor unit may be a microprocessor unit, but in the alternative, the processor unit may be any conventional processor unit, controller, microcontroller, or state machine. A processor unit may also be implemented as a combination of computing devices, e.g., a combination of a DSP and a microprocessor unit, a plurality of microprocessor units, one or more microprocessor units in conjunction with a DSP core, or any other such configuration.

The steps of a method or algorithm described in connection with the embodiments disclosed herein may be embodied directly in hardware, in a software module executed by a processor unit, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor unit such the processor unit can read information from, and write information to, the storage medium. In the alternative, the storage medium may be integral to the processor unit. The processor unit and the storage medium may reside in an ASIC. The ASIC may reside in a user terminal. In the alternative, the processor unit and the storage medium may reside as discrete components in a user terminal.

In one or more exemplary embodiments, the functions described may be implemented in hardware, software, firmware, or any combination thereof. If implemented in software as a computer program product, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

1. A method for scheduling workpieces on multiple batch processing machines in a factory, comprising:
establishing a scheduling model based on multiple scheduling objectives of the multiple batch processing machines and the workpieces, wherein the multiple scheduling objectives include meeting delivery dates of the workpieces, improving capacity utilization rate and batch sizes of the batch processing machines, and reducing production cycle time of the workpieces, and
applying Genetic Algorithm to determine an optimal scheduling scheme of the scheduling model.

2. The method according to claim 1, wherein the applying the Genetic Algorithm to determine the optimal scheduling scheme of the scheduling model comprises:
constructing an initial population based on process parameters of the workpieces and of the multiple batch processing machines, wherein the initial population includes several chromosomes, wherein each of the several chromosomes corresponds to a scheduling scheme that satisfies the scheduling model;
iterating the Genetic Algorithm to among the initial population to determine an optimal chromosome; and
decoding the optimal chromosome to obtain an optimal scheduling scheme corresponding to the optimal chromosome.

3. The method according to claim 2, wherein the constructing the initial population based on the process parameters of the workpieces and of the multiple batch processing machines comprises:
setting a chromosome population size; and
applying a double layer code design to generate the several chromosomes which satisfy the population size based on the process parameters of the workpieces and of the multiple batch processing machines to construct the initial population, wherein the double layer code design conforms to the scheduling model.

4. The method according to claim 3, wherein the constructing the initial population based on the process parameters of the workpieces and of the multiple batch processing machines further comprises:
reading data of calculation examples to obtain the process parameters of the workpieces; and
setting the process parameters of the multiple batch processing machines.

5. The method according to claim 3, wherein applying the double layer code design comprises:
performing a first layer code based on a number and conditions of the workpieces, wherein the first layer code includes multiple sub-layers, wherein each of the multiple sub-layers corresponds to one condition; and
applying a random function to initialize the multiple sub-layers and a second layer code under constraints of a number and conditions of the multiple batch processing machines.

6. The method according to claim 2, wherein iterating the Genetic Algorithm among the initial population to determine the optimal chromosome comprises:
setting a number of genetic iterations, parameters of genetic operation, and a fitness function, wherein the parameters of the genetic operation include mutation probability, crossover probability, and selection method;
iterating the Genetic Algorithm on the initial population;
in a response that the number of genetic iterations is reached, ending the iterating of the Genetic Algorithm; and
defining the optimal chromosome as a chromosome with a largest fitness value after a last Genetic Algorithm iteration, wherein the fitness value is a value of the chromosome corresponding to the fitness function.

7. The method according to claim 6, wherein each iteration of the Genetic Algorithm comprises:
performing a mutation operation and a crossover operation on the chromosomes from a previous Genetic Algorithm iteration based on the mutation probability and the crossover probability to generate new chromosomes;
calculating the fitness value of each of the new chromosomes based on the fitness function; and
applying the selection method to the new chromosomes based on the fitness value of each of the new chromosomes, wherein only chromosomes meeting the population size are selected in a present iteration of the Genetic Algorithm.

8. The method according to claim 7, wherein the setting fitness function comprises:
setting the fitness function based on an objective function of the scheduling model; and
calculating the fitness value of each new chromosome based on the fitness function, wherein the calculating comprises:
decoding each new chromosome according to designing rules of the double layer code design to obtain the scheduling scheme corresponding to the new chromosome;
determining an objective function value based on the scheduling scheme; and
calculating the fitness value of each new chromosome based on the objective function value and the fitness function.

9. The method according to claim 3, wherein the objective function is related to a completion time of the scheduling scheme, and wherein the decoding the chromosome to obtain the corresponding scheduling scheme comprises:
splitting the double layer code design of the chromosomes to obtain a sub-layer workpiece sequence and a batch size corresponding to the chromosomes respectively;
matching the sequence of the sub-layer workpieces to the batch size to form a batch result;
obtaining a start time and an operation time of each batch of workpieces according to the parameters of each batch of workpieces; and
according to the sequence of the sub-layer workpieces, scheduling the batch results based on a scheduling principle to generate a scheduling scheme corresponding to the new chromosomes.

10. The method according to claim 8, wherein the objective function is related to a completion time of the scheduling scheme, and the decoding the chromosome to obtain the corresponding scheduling scheme comprises:
splitting the double layer code design of the chromosomes to obtain a sub-layer workpiece sequence and a batch size corresponding to the chromosomes respectively;
matching the sequence of the sub-layer workpieces to the batch size to form a batch result;
obtaining a start time and an operation time of each batch of workpieces according to the parameters of each batch of workpieces; and
according to the sequence of the sub-layer workpieces, scheduling the batch results based on a scheduling principle to generate a scheduling scheme corresponding to the chromosomes.

11. The method of claim 1, further comprising:
scheduling the workpieces to the multiple batch processing machines for processing based on the optimal scheduling scheme.

12. A batch processing machine scheduling device for scheduling workpieces on multiple batch processing machines, comprising:
a memory unit; and
a processor unit coupled to the memory unit, wherein the processor unit is configured to:
establish a scheduling model based on multiple scheduling objectives of the multiple batch processing machines and the workpieces, wherein the multiple scheduling objectives include meeting delivery dates of the workpieces, improving capacity utilization rate and batch sizes of the batch processing machines, and reducing production cycle time of the workpieces; and
apply Genetic Algorithm to determine an optimal scheduling scheme of the scheduling model.

13. The batch processing machine scheduling device according to claim 12, wherein the processor unit is further configured to:
construct an initial population based on process parameters of the workpieces and of the multiple batch processing machines, wherein the initial population includes a number of chromosomes, wherein each of the chromosome corresponds to a scheduling scheme that satisfies the scheduling model;
iterating the Genetic Algorithm among the initial population to determine an optimal chromosome; and decode the optimal chromosome to obtain an optimal scheduling scheme corresponding to the optimal chromosome.

14. The batch processing machine scheduling device according to claim 13, wherein the processor unit is further configured to:
set a chromosome population size; and
apply a double layer code design to generate chromosomes which satisfy the population size based on the process parameters of the workpieces and of the multiple batch processing machines to construct the initial population, wherein the double layer code design conforms to the scheduling model.

15. The batch processing machine scheduling device according to claim 14, wherein the processor unit is further configured to:
read data of calculation examples to obtain the process parameters of the workpieces; and
set the process parameters of the batch processing machines.

16. The batch processing machine scheduling device according to claim 14, wherein the processor unit is further configured to:
perform a first layer code design based on a number and conditions of the workpieces, the first layer code design includes multiple sub-layers, and each sub-layer corresponds to one condition; and
use a random function to initialize the multiple sub-layers and a second layer code under constraints of the number and conditions of the multiple batch processing machines.

17. The batch processing machine scheduling device according to claim 13, wherein the processor unit is further configured to:
set a number of genetic iterations, parameters of genetic operation, and a fitness function, wherein the parameters of genetic operation include mutation probability, crossover probability, and selection method;
perform the Genetic Algorithm iteration on the initial population;
in a response that the number of genetic iterations is reached, reaches the number of genetic iterations, end the iterating of the Genetic Algorithm; and
define the optimal chromosome as a chromosome with a largest fitness value after a last Genetic Algorithm iteration, wherein the fitness value is a value of the chromosome corresponding to the fitness function.

18. The batch processing machine scheduling device according to claim 17, wherein the processor unit is further configured to:
perform a mutation operation and a crossover operation on the chromosomes of a previous Genetic Algorithm iteration based on the mutation probability and the crossover probability to generate new chromosomes;
calculate the fitness value of each of the new chromosomes based on the fitness function; and
applying the selection method to the new chromosomes based on the fitness value of each of the new chromosomes, wherein only chromosomes meeting the population size are selected in a present iteration of the Genetic Algorithm.

19. The batch processing machine scheduling device according to claim 18, wherein the processor unit is further configured to:
set the fitness function based on the objective function of the scheduling model; and
decode each of the new chromosomes according to designing rules of the double layer code design to obtain the scheduling scheme corresponding to the new chromosomes;
determine an objective function value based on the scheduling scheme; and
calculate the fitness value of each of the new chromosomes based on the objective function value and the fitness function.

20. The batch processing machine scheduling device according to claim 13, wherein the objective function is related to a completion time of the scheduling scheme, wherein the processor unit is further configured to:
split the double layer code design of the chromosomes to obtain a sub-layer workpieces sequence and a batch size corresponding to the chromosomes respectively;
match the sequence of the sub-layer workpieces to the batch size to form a batch result;
obtain a start time and an operation time of each batch of workpieces according to the process parameters of each batch of workpieces; and
according to the sequence of the sub-layer workpieces, schedule the batch results based on a scheduling principle to generate a scheduling scheme corresponding to the chromosomes.

21-23. (canceled)
